(19) United States
(12) Patent Application Publication
(10) Pub. No.: US 2025/0037744 A1
(43) Pub. Date: Jan. 30, 2025

(54) SEMICONDUCTOR DEVICE

(71) Applicant: Renesas Electronics Corporation, Tokyo (JP)

(72) Inventors: Toshiki KIRYU, Tokyo (JP); Toma OGATA, Tokyo (JP); Kosuke YAYAMA, Tokyo (JP); Toyohiro SHIMOGAWA, Tokyo (JP)

(21) Appl. No.: 18/777,820

(22) Filed: Jul. 19, 2024

(30) Foreign Application Priority Data
Jul. 25, 2023 (JP) 2023-120811

(51) Int. Cl. G11C 5/14; G11C 7/22; H02M 3/158

(52) U.S. Cl. CPC G11C 5/147; G11C 7/22; H02M 3/158

(57) ABSTRACT

While suppressing the influence of voltage noise, the adjustment range of the power supply voltage generated based on the reference voltage is expanded. The semiconductor device includes a reference voltage generation circuit, a regulator, a buffer, and a voltage control circuit. The reference voltage generation circuit is configured to be able to adjust the reference voltage. The regulator is configured to be able to change the output ratio of the power supply voltage to the reference voltage based on the control signal. The semiconductor device further includes a voltage control circuit for outputting a voltage control signal to the regulator to switch the output ratio.

### CROSS-REFERENCE TO RELATED APPLICATIONS

The disclosure of Japanese Patent Application No. 2023-120811 filed on Jul. 25, 2023, including the specification, drawings and abstract is incorporated herein by reference in its entirety.

### BACKGROUND

The present invention relates to a semiconductor device.

There are disclosed techniques listed below.
[Patent Document 1] Japanese Unexamined Patent Application Publication No. 2004-319034
[Patent Document 2] Japanese Unexamined Patent Application Publication No. 2007-193933

A power circuit mounted on an MCU (Micro Controller Unit) generates a power supply voltage VDD based on a reference voltage after power-on reset is released. Patent Document 1 and Patent Document 2 disclose a technology for adjusting the power supply voltage by trimming the reference voltage.

### SUMMARY

It is desired to expand the adjustment range of the power supply voltage generated based on the reference voltage while suppressing the influence of voltage noise.

Other objects and novel features will become apparent from the description of this specification and the accompanying drawings.

A semiconductor device according to one embodiment includes a reference voltage generating circuit that generates a reference voltage, a regulator that generates a power supply voltage based on the reference voltage, and a buffer that transmits the reference voltage from the reference voltage generating circuit to the regulator. The reference voltage generating circuit is configured to be able to adjust the reference voltage. The regulator is configured to be able to change the output ratio of the power supply voltage to the reference voltage. The semiconductor device further includes a voltage control circuit that outputs a voltage control signal to the regulator to switch the output ratio.

According to the one embodiment, it is possible to expand the adjustment range of the power supply voltage generated based on the reference voltage while suppressing the influence of voltage noise.

### BRIEF DESCRIPTION OF THE DRAWINGS

FIG. 1 is a diagram explaining the configuration of a semiconductor device related to a comparative example.

FIG. 2 is a diagram explaining the relationship between the power supply voltage and the voltage guarantee signal in the comparative example.

FIG. 3 is a diagram explaining the fluctuation range of the power supply voltage and the voltage detection value in the comparative example.

FIG. 4 is a diagram explaining the operation of the semiconductor device related to the comparative example.

FIG. 5 is a diagram explaining the problems of the semiconductor device related to the comparative example.

FIG. 6 is a diagram explaining the problems of the semiconductor device related to the comparative example.

FIG. 7 is a diagram explaining the configuration of a semiconductor device related to an examined example.

FIG. 8 is a diagram explaining the problems of the semiconductor device related to the examined example.

FIG. 9 is a diagram explaining the configuration of a semiconductor device related to the first embodiment.

FIG. 10 is a diagram representing the voltage noise in the semiconductor device related to the first embodiment.

FIG. 11 is a diagram explaining the operation of the regulator related to the first embodiment.

FIG. 12 is a diagram explaining the fluctuation range of the power supply voltage and the voltage detection value in the first embodiment.

FIG. 13 is a diagram explaining the operation of the semiconductor device related to the first embodiment.

FIG. 14 is a diagram explaining the configuration of a semiconductor device related to Embodiment 1 of the first embodiment.

FIG. 15 is a diagram explaining the configuration of a semiconductor device related to Embodiment 2 of the first embodiment.

### DETAILED DESCRIPTION

For clarity of explanation, the following descriptions and drawings are appropriately omitted and simplified. Each element described in the drawings as a function block performing various processes can be configured in hardware by a CPU, memory, and other circuits, and can be realized in software by a program loaded into memory, etc. Therefore, it is understood by those skilled in the art that these function blocks can be realized in various forms by hardware, software operating on hardware, or a combination thereof, and are not limited to any one. In the drawings, the same elements are denoted by the same reference numerals, and a repetitive description thereof is omitted as necessary.

The program mentioned above, when loaded into a computer, includes a group of instructions (or software code) for causing the computer to perform one or more functions described in the embodiment. The program may be stored in a non-temporary computer-readable medium or a tangible memory medium. Non-limiting examples of computer-readable media or tangible memory media include Random Access Memory (RAM), Read Only Memory (ROM), flash memory, Solid State Drive (SSD) or other memory technologies, CD-ROM, Digital Versatile Disc (DVD), Blu-ray (registered trademark) disc or other optical disc storage, magnetic cassette, magnetic tape, magnetic disk storage or other magnetic storage devices. The program may be transmitted on a temporary computer-readable medium or communication medium. Non-limiting examples of temporary computer-readable media or communication media include electrical, optical, acoustic, or other forms of propagation signals.

### Consideration Leading to the Embodiment

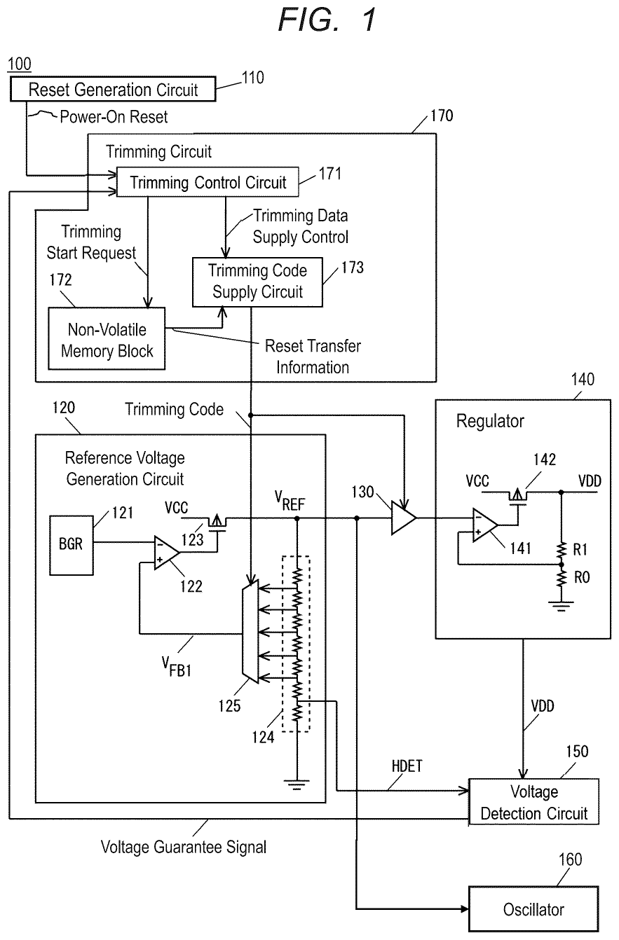

FIG. 1 is a diagram showing the configuration of a semiconductor device 100 according to a comparative example. The semiconductor device 100 includes a reset generation circuit 110, a reference voltage generation circuit 120, a buffer 130, a regulator 140, a voltage detection circuit 150, an oscillator 160, and a trimming circuit 170. The reset generation circuit 110 outputs a power-on reset to the trimming circuit 170 and the like.

The reference voltage generation circuit is a circuit that generates a reference voltage VREF, and is configured to be able to adjust the reference voltage VREF. The reference voltage generation circuit 120 includes a BGR (Bandgap Reference) 121, an operational amplifier 122, a p-type FET (Field Effect Transistor) 123, a series ladder resistor 124, and a selector 125. The BGR121 generates a BGR voltage VBGR. The BGR voltage VBGR is input to the negative input terminal of the operational amplifier 122. The output terminal of the operational amplifier 122 is connected to the gate terminal of the FET123. The source terminal of FET123 is connected to a power line supplying power voltage VCC, and the drain terminal of FET123 is connected to ground via ladder resistor 124. The power voltage VCC is also referred to as a primary power supply. The power voltage VDD, which will be described later, is also referred to as a secondary power supply. Selector 125 selects one node from multiple nodes on ladder resistor 124 based on a trimming code to be described later, and inputs the voltage (referred to as feedback loop voltage VFB1) of the selected one connection node to the positive input terminal of operational amplifier 122. The voltage (referred to as voltage detection value HDET) of a predetermined node included in the multiple nodes on ladder resistor 124 is supplied to voltage detection circuit 150. Reference voltage generation circuit 120 outputs the voltage of the node between FET123 and ladder resistor 124 as reference voltage VREF.

Buffer 130 transmits the reference voltage VREF generated by reference voltage generation circuit 120 to regulator 140. The characteristics of the elements included in buffer 130 are adjusted based on the trimming code. Buffer 130 may be, for example, a voltage follower circuit including an operational amplifier.

The regulator 140 includes an operational amplifier 141, a p-type FET 142, a resistor RO, and a resistor R1. The negative input terminal of the operational amplifier 141 is connected to the output terminal of the buffer 130. The output terminal of the operational amplifier 141 is connected to the gate terminal of the FET 142. The source terminal of the FET 142 is connected to a power line that supplies the power supply voltage VCC. The drain terminal of the FET 142 is connected to one end of the resistor R1. The other end of the resistor R1 is connected to one end of the resistor RO. The other end of the resistor RO is connected to the ground. The voltage at the node between the resistors RO and RI is input to the positive input terminal of the operational amplifier 141. The regulator 140 outputs the voltage at the node between the FET 142 and the resistor RI as the power supply voltage VDD. The power supply voltage VDD is also referred to as the secondary power supply. The power supply voltage VDD is supplied to the non-volatile memory block 172 to be described later, and the power supply voltage VCC is supplied to other circuits.

The voltage detection circuit 150 includes a circuit that detects when the power supply voltage VDD exceeds the voltage detection value HDET and a circuit that detects when the power supply voltage VDD exceeds the voltage detection value LDET. The voltage detection value LDET may be supplied from the reference voltage generation circuit 120, like the voltage detection value HDET. The voltage detection value LDET is lower than the voltage detection value HDET. When the power supply voltage VDD exceeds the voltage detection value HDET, the voltage detection circuit 150 outputs a voltage guarantee signal to the trimming circuit 170.

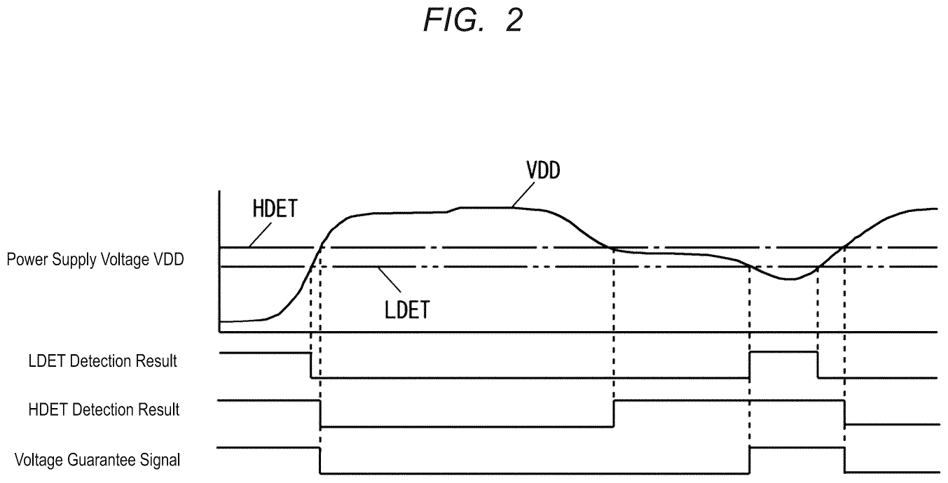

FIG. 2 is a diagram explaining the relationship between the power supply voltage VDD and the voltage guarantee signal. In the top graph, the power supply voltage VDD is shown by a solid line, the voltage detection value HDET is shown by a dotted line, and the voltage detection value LDET is shown by a dashed line. The voltage detection value HDET is also referred to as the first threshold, and the voltage detection value LDET is also referred to as the second threshold. At power-on, when the power supply voltage VDD exceeds the voltage detection value HDET, a voltage guarantee signal (L level) is output. During normal operation, as long as the power supply voltage VDD exceeds the voltage detection value LDET, the output of the voltage guarantee signal continues. When the voltage detection circuit 150 detects that the power supply voltage VDD has fallen below the voltage detection value LDET, it terminates the output of the voltage guarantee signal. The output operation of the voltage guarantee signal has hysteresis, which provides a margin against a drop in the power supply voltage VDD.

Referring to FIG. 1, the oscillator 160 generates a clock signal based on the reference voltage VREF. The trimming circuit 170 includes a trimming control circuit 171, a non-volatile memory block 172, and a trimming code supply circuit 173. When the trimming control circuit 171 receives a power-on reset, it performs a reset operation. When the trimming control circuit 171 receives a voltage guarantee signal, it outputs a trimming start request to the non-volatile memory block 172. Then, the trimming control circuit 171 outputs a signal (referred to as trimming data supply control) to control the supply of trimming codes by the trimming code supply circuit 173 to the trimming code supply circuit 173. The non-volatile memory block 172 stores information (referred to as a trimming code) used to adjust the reference voltage VREF. The trimming code may include information for adjusting the characteristics of the elements included in the buffer 130. When the non-volatile memory block 172 receives a trimming start request, it outputs reset transfer information including a trimming code to the trimming code supply circuit 173. The trimming code supply circuit 173 outputs the trimming code read from the non-volatile memory block 172 to the selector 125 and the buffer 130 in accordance with the trimming data supply control.

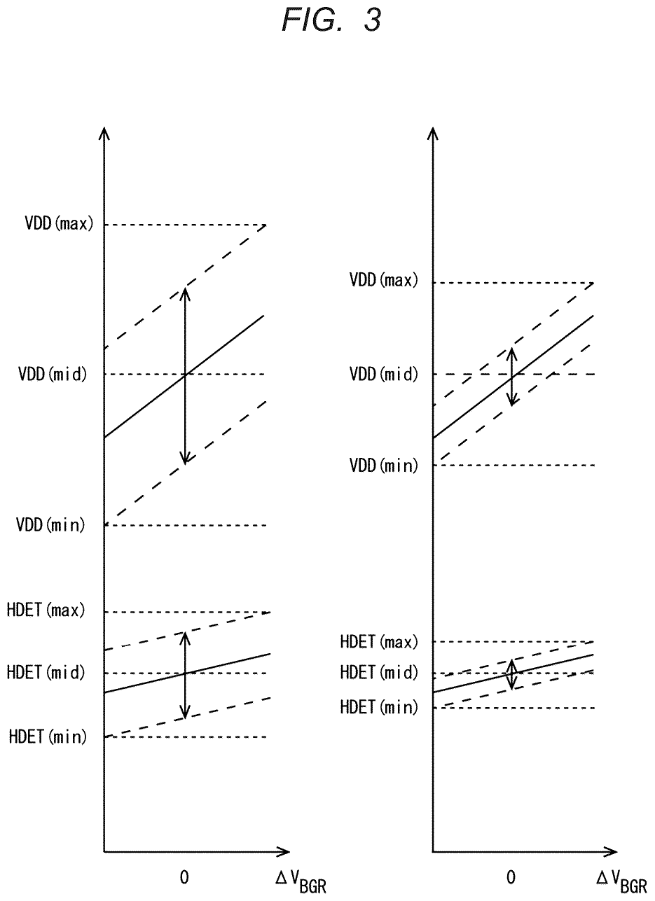

FIG. 3 is a diagram explaining the fluctuation range of the power supply voltage VDD and the voltage detection value HDET with respect to the variation ΔVBGR of the BGR voltage VBGR. The left diagram shows the fluctuation range of the power supply voltage VDD and the voltage detection value HDET before trimming. The right diagram shows the fluctuation range of the power supply voltage VDD and the voltage detection value HDET after trimming. The horizontal axis represents ΔVBGR, and the vertical axis represents voltage.

The reference voltage generation circuit 120 generates a reference voltage VREF based on the BGR voltage VBGR. The power supply voltage VDD and the voltage detection value HDET are generated based on the reference voltage VREF. Therefore, in a steady state, the power supply voltage VDD is proportional to the BGR voltage VBGR, and the voltage detection value HDET is proportional to the BGR voltage VBGR. Therefore, a linear variation with respect to ΔVBGR propagates to the power supply voltage VDD and the voltage detection value HDET.

The solid line on the upper side of each figure represents the power supply voltage VDD, and the solid line on the lower side represents the voltage detection value HDET. The double arrows on the upper side represent the variation of the power supply voltage VDD when ΔVBGR is fixed. The changes in the upper and lower limits of the variation of the power supply voltage VDD are shown by dotted lines. The double arrows on the lower side represent the variation of HDET when ΔVBGR is fixed. The changes in the upper and lower limits of the variation of the voltage detection value HDET are shown by dotted lines. Due to the variation ΔVBGR of the BGR voltage VBGR, the fluctuation range of the power supply voltage VDD becomes a range of VDD (min) or more and VDD (max) or less. Similarly, due to the variation ΔVBGR of the BGR voltage VBGR, the fluctuation range of the voltage detection value HDET becomes a range of HDET (min) or more and HDET (max) or less. Referring to the right figure, the fluctuation range of the power supply voltage VDD after trimming is narrower than the fluctuation range of the power supply voltage VDD before trimming. Similarly, the fluctuation range of the voltage detection value HDET after trimming is narrower than the fluctuation range of the voltage detection value HDET before trimming.

The main cause of the fluctuation of the power supply voltage VDD is the differential mismatch of the operational amplifier 141 included in the regulator 140. The main cause of the fluctuation of the voltage detection value HDET is the differential mismatch of the operational amplifier (not shown) included in the voltage detection circuit 150. Since the manufacturing variations of the regulator 140 and the voltage detection circuit 150 are independent of each other, the power supply voltage VDD and the voltage detection value HDET fluctuate independently.

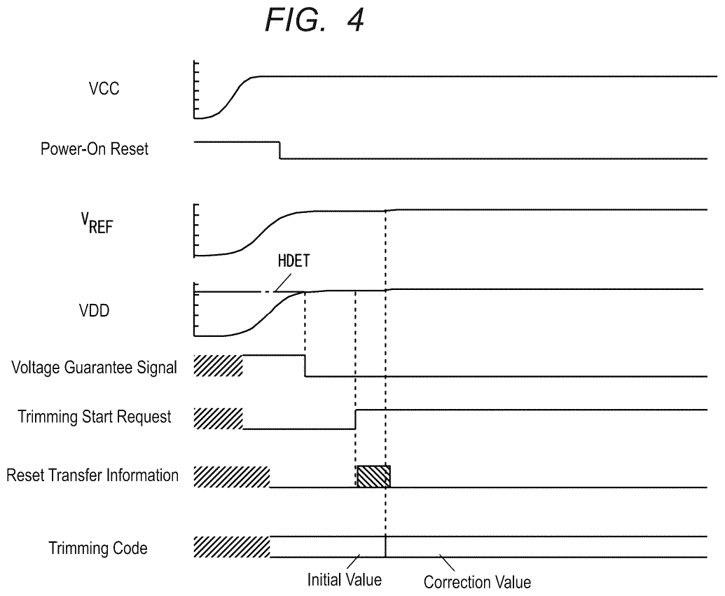

FIG. 4 is a diagram explaining the operation of the semiconductor device 100. When the power supply voltage VCC exceeds the threshold, the power-on reset is released. Then, when the power supply voltage VDD exceeds the voltage detection value HDET, a voltage guarantee signal (L level) is output. Then, the trimming control circuit 171 outputs a trimming start request (H level), and the non-volatile memory block 172 outputs reset transfer information. Then, the trimming code supply circuit 173 changes trimming code from the initial value to the correction value.

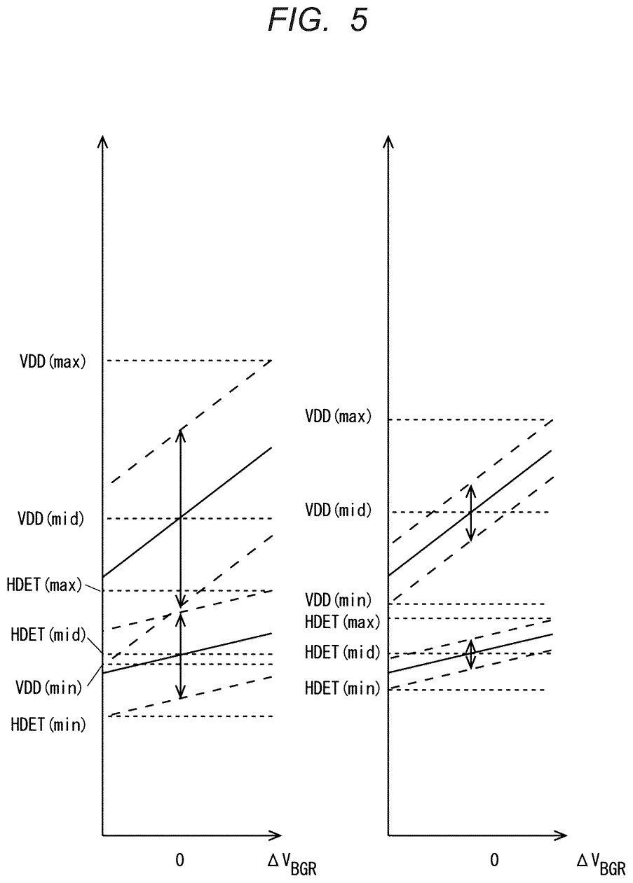

Next, I will explain the problem that the inventor of the present invention newly found about the semiconductor device 100. In the semiconductor device 100, since the power supply voltage VDD and the voltage detection value HDET fluctuate independently, as the MCU is low-voltage, the power supply voltage VDD before trimming may be lower than the voltage detection value HDET. FIG. 5 is a diagram explaining the fluctuation range of the power supply voltage VDD and the voltage detection value HDET when the power supply voltage VDD is low. As with FIG. 3, the left figure represents the fluctuation range before trimming, and the right figure represents the fluctuation range after trimming. Referring to the left figure, the minimum value VDD (min) of the power supply voltage VDD is lower than the maximum value HDET (max) of the voltage detection value HDET. Therefore, there is a possibility that the power supply voltage VDD may be lower than the voltage detection value HDET.

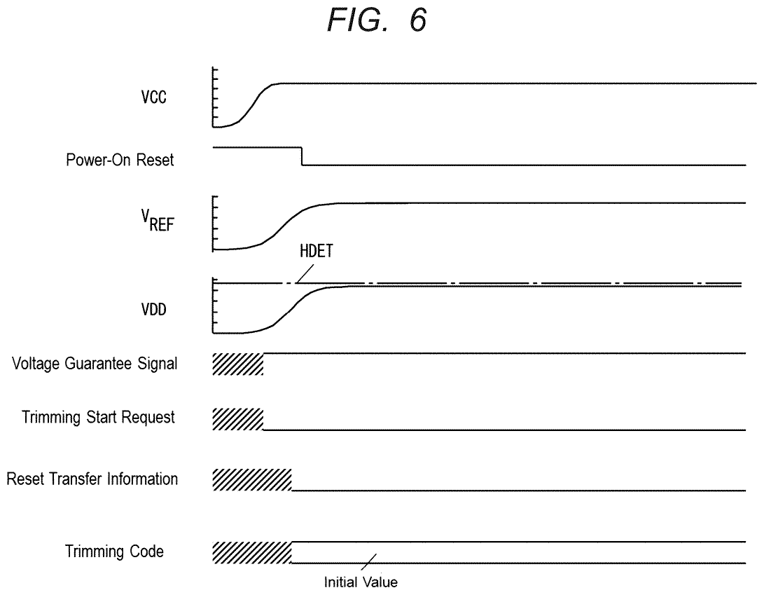

When the power supply voltage VDD before trimming is lower than the voltage detection value HDET, the voltage detection circuit 150 does not output a voltage guarantee signal to the trimming control circuit 171. Then, the trimming control circuit 171 does not output a trimming request to the non-volatile memory block 172. Therefore, the semiconductor device 100 cannot adjust the reference voltage VREF. FIG. 6 is a diagram explaining the operation of the semiconductor device 100 when the power supply voltage VDD is lower than the voltage detection value HDET. Since the power supply voltage VDD does not exceed the voltage detection value HDET, the voltage guarantee signal (L level) is not output. The trimming code remains at the initial value, and the reference voltage VREF is not trimmed.

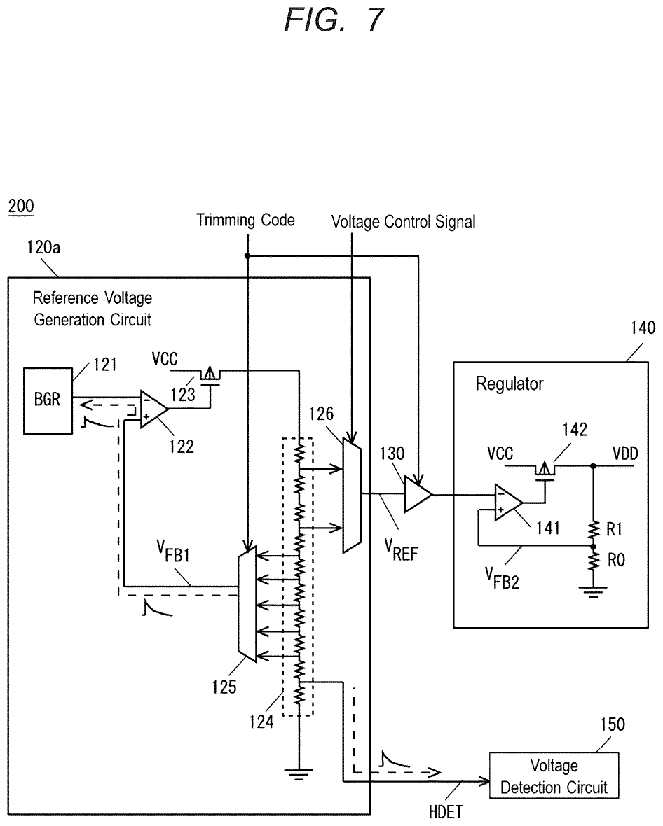

The inventor of the present invention has considered increasing the initial power supply voltage VDD higher than the power supply voltage VDD during normal operation to solve the above problem, so that the power supply voltage VDD, which has fluctuated downward, becomes higher than the voltage detection value HDET. FIG. 7 is a diagram explaining the configuration of the semiconductor device 200 according to the examined example. The illustrations of the reset generation circuit 110, the oscillator 160, and the trimming circuit 170 are omitted. Comparing FIG. 1 and FIG. 7, the reference voltage generation circuit 120 has been replaced with the reference voltage generation circuit 120a. The reference voltage generation circuit 120a further includes a selector 126. The selector 126 has a function to switch the height of the reference voltage VREF output to the buffer 130 based on a voltage control signal supplied from outside the reference voltage generation circuit 120a. The selector 126 can be said to coarsely adjust the reference voltage VREF compared to the selector 125. The semiconductor device 200 can trim the reference voltage VREF even when the power supply voltage VDD is lower than the voltage detection value HDET by increasing the reference voltage VREF at the time of power-on.

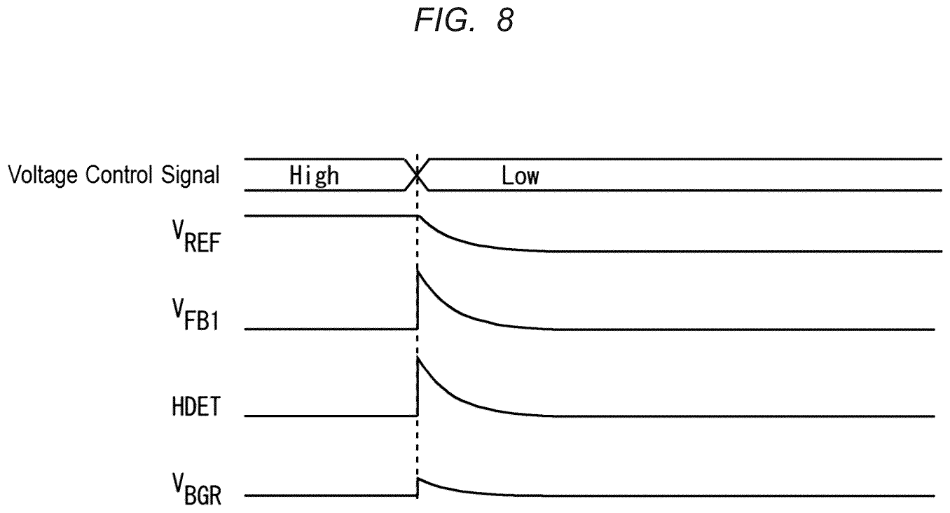

Next, the problems of the semiconductor device 200 will be explained. When the selector 126 switches the height of the reference voltage VREF, charge movement occurs from the selected node. Therefore, transient switching noise propagates to the feedback loop voltage VFB1 and the voltage detection value HDET. The dotted arrow indicates the path through which the switching noise propagates. The voltage noise generated in the feedback loop voltage VFB1 propagates to BGR121 through the capacitive coupling included in the differential amplification circuit of the operational amplifier 122. The voltage noise propagated to BGR121 deteriorates the accuracy of the BGR voltage VBGR, and the voltage noise propagated to the voltage detection circuit 150 deteriorates the accuracy of the voltage detection value HDET. FIG. 8 shows the time change of the reference voltage VREF, the feedback loop voltage VFB1, the voltage detection value HDET, and the BGR voltage VBGR when the height of the reference voltage VREF is switched using a voltage control signal. If the accuracy of the power supply voltage VDD decreases, the frequency accuracy of the oscillator may also decrease through the power supply voltage VDD.

Based on the above considerations, the inventor of the present invention conceived the following embodiments.

### First Embodiment

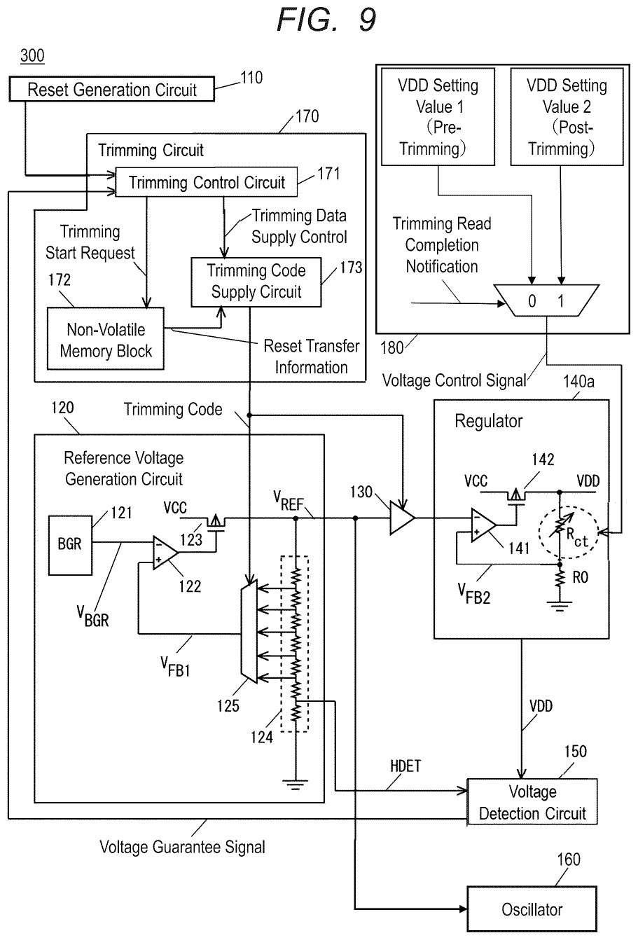

FIG. 9 is a circuit diagram showing the configuration of the semiconductor device 300 according to the first embodiment. Comparing FIG. 1 and FIG. 9, the regulator 140 has been replaced with the regulator 140a. And the semiconductor device 300 further includes a voltage control circuit 180.

The regulator 140a is configured to be able to change the output ratio of the power supply voltage VDD to the reference voltage VREF. For example, the resistor R1 may be configured as a variable resistor Rct. The output voltage VOUT of the operational amplifier 141 is expressed as VOUT=(1+Rct/R0) VREF. Alternatively, a series ladder resistor (not shown) may be arranged between the power line that outputs the power supply voltage VDD and the ground, and a selector (not shown) that selects one node from multiple nodes may be provided. The voltage of the selected one node is input to the negative input terminal of the operational amplifier 141. The voltage input to the negative input terminal of the operational amplifier 141 is called the feedback loop voltage VFB2.

The voltage control circuit 180 outputs a voltage control signal for switching the output ratio of the power supply voltage VDD to the reference voltage VREF to the regulator 140a. Specifically, the voltage control circuit 180 outputs a pre-trimming setting value (VDD setting value 1) or a post-trimming setting value (VDD setting value 2) as a voltage control signal based on an external notification (referred to as a trimming read completion notification). If the voltage control trimming read completion notification is not input, the voltage control circuit 180 outputs a setting value (for example, “0”) for outputting a high power supply voltage VDD to the regulator 140a. If the trimming completion notification is input, the voltage control circuit 180 outputs a setting value (for example, “1”) for outputting a low power supply voltage VDD to the regulator 140a. “0” represents the L level, and “1” represents the H level. The trimming read completion notification may be transmitted from the non-volatile memory block 172, or may be transmitted from a counter (not shown). The voltage control circuit 180 may, for example, change the power supply voltage VDD by about 0.1V.

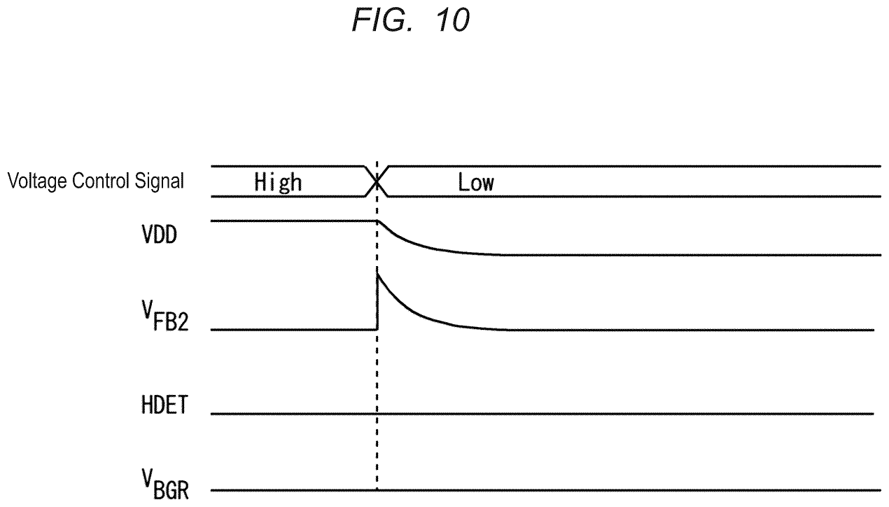

Similar to the examined example, voltage noise is generated due to fluctuations in the power supply voltage VDD, but the voltage noise propagated to BGR121 and voltage detection circuit 150 is small. This is because the voltage noise propagates through buffer 130. Therefore, the semiconductor device 300 can suppress the influence of voltage noise on the BGR voltage VBGR and the voltage detection value HDET. FIG. 10 is a graph showing the temporal changes in the voltage detection value HDET and the BGR voltage VBGR. The power supply voltage VDD and the feedback loop voltage VFB2 fluctuate according to the switching of the voltage control signal, but the voltage noise propagated to the voltage detection value HDET and the BGR voltage VBGR is small.

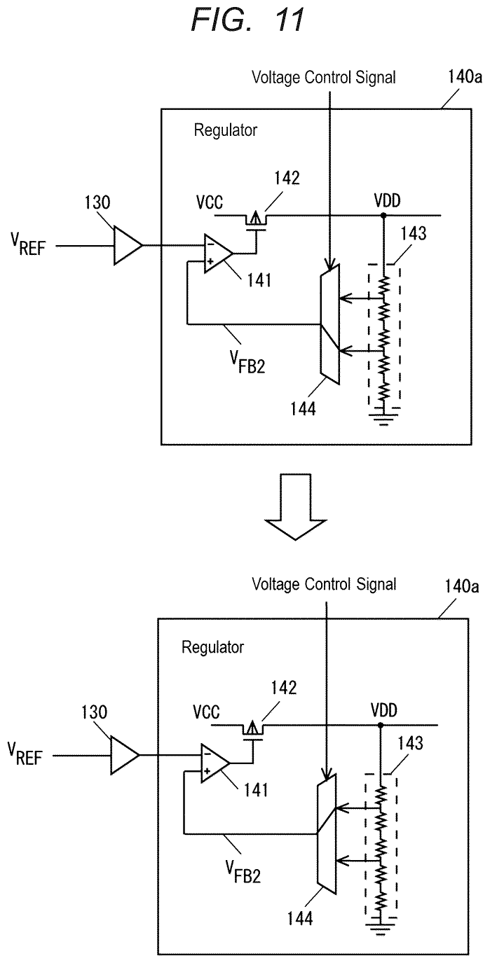

FIG. 11 is a diagram explaining the operation of regulator 140a. The upper diagram shows the operation of regulator 140a before trimming the reference voltage VREF. The lower diagram shows the operation of regulator 140a after trimming the reference voltage VREF. The regulator 140a includes a ladder resistor 143 and a selector 144. The series-type ladder resistor 143 is arranged between the power line supplying the power supply voltage VDD and the ground. The selector 144 selects one node from two nodes on the ladder resistor 143 based on the voltage control signal. The selector 144 may be composed of one or more switches. The voltage of the selected one node is input to the operational amplifier 141 as the feedback loop voltage VFB2. Before trimming, the selector 144 inputs a low feedback loop voltage VFB2 to the operational amplifier 141, and after trimming, it inputs a high feedback loop voltage VFB2 to the operational amplifier 141.

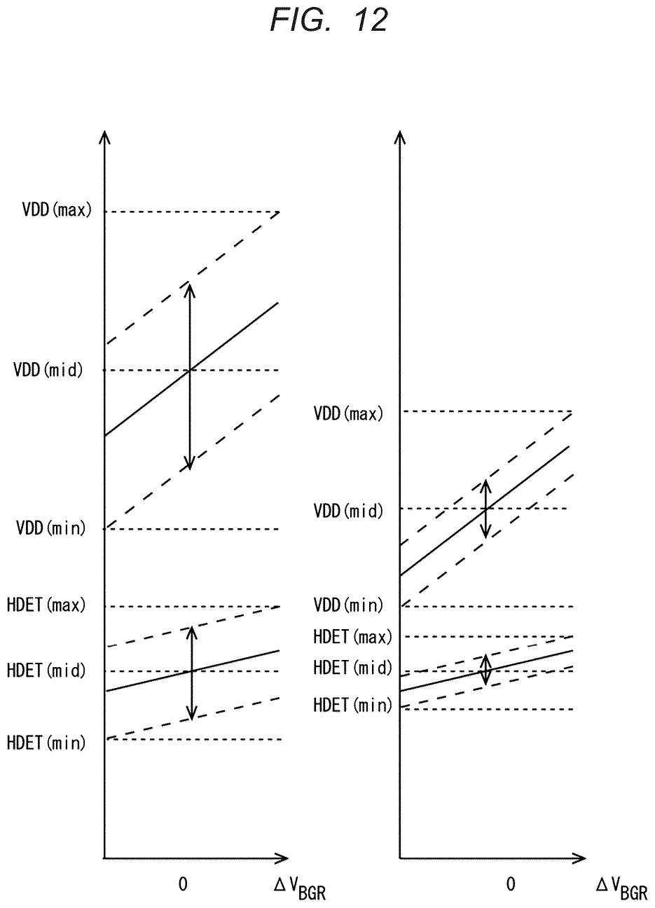

FIG. 12 is a diagram explaining the fluctuation range of the power supply voltage VDD and the voltage detection value HDET in the semiconductor device 100. Referring to the left diagram, the power supply voltage VDD is set high so that the minimum value VDD (min) of the power supply voltage VDD is higher than the maximum value HDET (max) of the power supply voltage HDET. Referring to the right diagram, the power supply voltage VDD after trimming is set to a low value.

In the semiconductor device 100, after the power supply voltage VDD exceeds the voltage detection value HDET (first threshold), the output ratio of the power supply voltage VDD to the reference voltage VREF is switched from the first output ratio to the second output ratio, which is smaller than the first output ratio. This allows the semiconductor device 100 to reliably trim the reference voltage VREF.

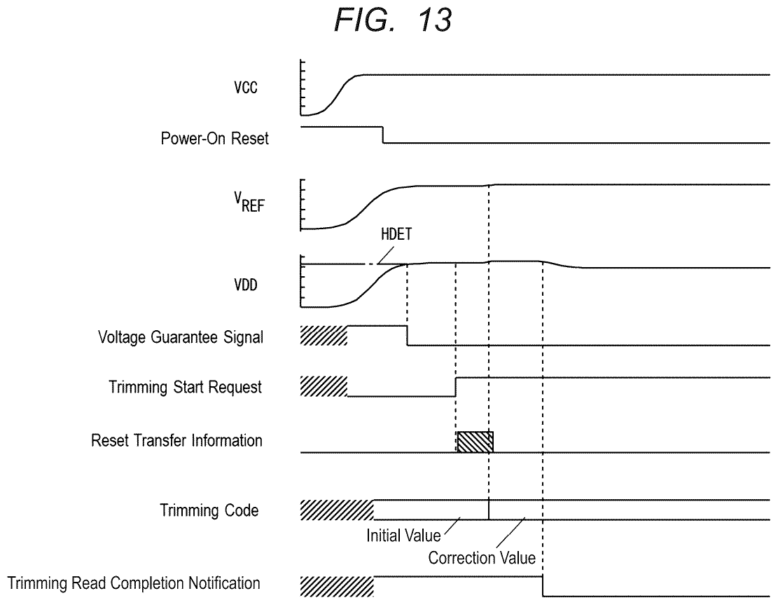

FIG. 13 is a diagram explaining the operation of the semiconductor device 300. When the power supply voltage VDD exceeds the voltage detection value HDET, a voltage guarantee signal (L level) is output. Then, a trimming start request (H level) is output, and the transmission of reset transfer information begins. Then, the trimming code is changed from the initial value to the correction value, and the reference voltage VREF is trimmed. This results in a fine adjustment of the power supply voltage VDD. After the reference voltage VREF is trimmed, a trimming read completion notification (L level) is output, and the power supply voltage VDD changes to a low value.

The semiconductor device 300 according to the first embodiment can expand the adjustment range of the power supply voltage VDD while suppressing the effects of voltage noise generation. The semiconductor device 300 can prevent the voltage noise from propagating to BGR121, voltage detection circuit 150, etc., and prevent the accuracy of the power supply voltage VDD and the voltage detection value HDET from decreasing. In addition, the semiconductor device 300 can prevent the trimming of the reference voltage from not being performed by expanding the adjustment range of the power supply voltage VDD.

### Embodiment 1

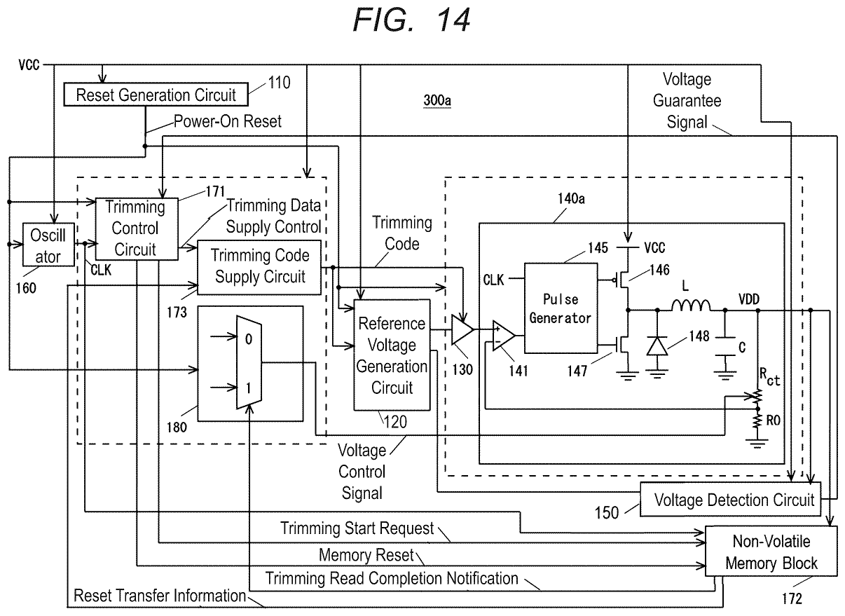

Next, the semiconductor device 300a according to Embodiment 1, which is a specific example of the first embodiment, will be described. FIG. 14 is a diagram explaining the configuration of the semiconductor device 300a according to Embodiment 1. Comparing FIGS. 9 and 14, the regulator 140a is configured as a DCDC converter. The clock signal CLK generated by the oscillator 160 is supplied to the trimming control circuit 171 and the non-volatile memory block 172. The non-volatile memory block may be, for example, MRAM (Magnetoresistive Random Access Memory), or it may be flash memory. In addition to the trimming start request, the trimming control circuit 171 outputs a memory reset to the non-volatile memory block 172.

The regulator 140a further includes a pulse generator 145, a p-type MOSFET 146, an n-type MOSFET 147, a diode 148, an inductor L, and a capacitor C. The source terminal of the MOSFET 146 is connected to a power line that supplies the power supply voltage VCC. The drain terminals of the MOSFET 146 and the MOSFET 147 are interconnected. The source terminal of the MOSFET 147 is connected to the ground GND. The pulse generator 145 switches the on and off of the MOSFETs 146 and 147 based on the output voltage of the operational amplifier 141 and the clock signal CLK. The voltage at the node between the MOSFETs 146 and 147 is output as the power supply voltage VDD through the inductor L. The anode terminal of the diode 148 is connected to the ground GND. The cathode terminal of the diode 148 is connected to the node between the MOSFET 147 and the inductor L. The capacitor C is placed between the power line that outputs the power supply voltage VDD and the ground GND.

The dotted lines surrounding the buffer 130 and the regulator 140a indicate that these circuits are supplied with the power supply voltage VCC. The dotted lines surrounding the trimming control circuit 171, the trimming code supply circuit 173, and the voltage control circuit 180 indicate that these circuits are supplied with the power supply voltage VCC. In addition, the power supply voltage VCC is supplied to the reset generation circuit 110, the reference voltage generation circuit 120, the voltage detection circuit 150, and the oscillator 160. The non-volatile memory block 172 is supplied with the power supply voltage VDD generated by the regulator 140.

The operation of the semiconductor device 300a according to Embodiment 1 will be described. After power-on, when the power supply voltage VCC becomes equal to or higher than a threshold, the reset generation circuit 110 releases the power-on reset, and the oscillator 160 starts oscillation. In parallel with the release of the power-on reset and the start of oscillation, the regulator 140a generates the power supply voltage VDD based on the power supply voltage VCC in accordance with the voltage control signal generated by the voltage control circuit 180. Then, the voltage detection circuit 150 detects that the power supply voltage VDD is within the voltage guarantee range, that is, the power supply voltage VDD has exceeded the voltage detection value HDET, and outputs a voltage guarantee signal to the trimming control circuit 171. Then, the trimming control circuit 171 outputs a memory reset and a trimming start request to the non-volatile memory block 172. Note that the power-on reset of the trimming control circuit 171 is released, and a clock is supplied to the trimming control circuit 171 from the oscillator 160. Then, reset transfer information including a trimming code is read from the non-volatile memory block 172, and the trimming code is stored in the trimming code supply circuit 173. Then, the reference voltage VREF generated by the reference voltage generation circuit 120 is fine-tuned. Then, the non-volatile memory block 172 outputs a trimming read completion notification to the voltage control circuit 180. Upon receiving the trimming code completion notification, the voltage control circuit 180 changes the power supply voltage VDD by outputting a voltage control signal to the regulator 140a. The power supply voltage VDD is changed from a high voltage (for example, 0.9V) to a low voltage (for example, 0.8V).

Note that in FIG. 13, the regulator 140a constitutes a step-down DCDC converter, but the regulator 140a may constitute a step-up DCDC converter or a linear regulator.

In the semiconductor device 300a according to Embodiment 1, the non-volatile memory block 172 that stores the trimming code can notify the voltage control circuit 180 of the appropriate timing for switching the power supply voltage VDD.

### Embodiment 2

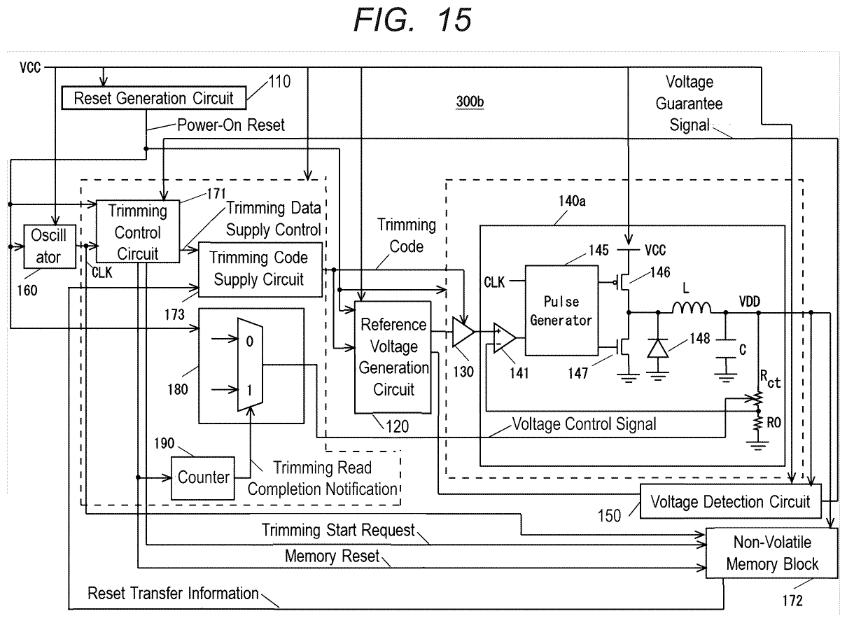

Next, the semiconductor device 300b according to Embodiment 2, which is a specific example of the first embodiment, will be described. FIG. 15 is a diagram explaining the configuration of the semiconductor device 300b according to Embodiment 2. Comparing FIG. 14 and FIG. 15, the semiconductor device 300b further includes a counter 190. The power supply voltage VCC is supplied to the counter 190. The trimming control circuit 171 outputs a memory reset to the non-volatile memory block 172 and the counter 190. The counter 190 starts counting upon receiving memory reset. When the count reaches a predetermined number corresponding to the period until the reference voltage VREF is trimmed, the counter 190 sends a trimming read completion notification to the voltage control circuit 180. This ensures a sufficient period from the output of the memory reset to the output of the trimming read completion notification (referred to as the trimming read period). The trimming read completion notification can also be said to notify the timing of outputting the voltage control signal.

The operation of the semiconductor device 300b will be described. After power-on, when the power supply voltage VCC exceeds the threshold, the reset generation circuit 110 releases the power-on reset, and the oscillator 160 starts oscillating. When the trimming control circuit 171 outputs a memory reset and a trimming start request to the non-volatile memory block 172, the counter 190 starts counting the number of pulses of the clock signal generated by the oscillator 160. The counter 190 can guarantee the length of the trimming read period. Then, the trimming code is read from the non-volatile memory block 172 and stored in the trimming code supply circuit 173. Then, when the counted number of pulses reaches a predetermined number, the counter 190 outputs a trimming read completion notification to the voltage control circuit 180, and the voltage control circuit 180 changes the power supply voltage VDD. As with Embodiment 1, the regulator 140a may be configured as a step-up DCDC converter or a linear regulator.

In the semiconductor device 300b according to Embodiment 2, the counter 190 can notify the voltage control circuit 180 of the appropriate timing to switch the power supply voltage VDD.

Finally, the effect of the semiconductor device 300 according to the first embodiment will be described. The semiconductor device 300 can expand the adjustment range of the power supply voltage VDD while maintaining the accuracy of both the voltage detection value HDET and the power supply voltage VDD without significantly changing the circuit area.

With the semiconductor device 300, the operating voltage during normal operation of the MCU can be determined based on the relationship between the variation range of the power supply voltage VDD after trimming and the electrical characteristics in the process, regardless of the variation range of the power supply voltage VDD before trimming. Therefore, the semiconductor device 300 can contribute to the reduction of the operating voltage of the MCU.

Although the invention made by the present inventor has been specifically described based on the embodiment, the present invention is not limited to the embodiment described above, and it is needless to say that various modifications can be made without departing from the gist thereof.

What is claimed is:

1. A semiconductor device comprising:
a reference voltage generating circuit configured to generate a reference voltage,
a regulator circuit configured to generate a power supply voltage based on the reference voltage, and
a buffer circuit configured to transmit the reference voltage from the reference voltage generating circuit to the regulator circuit,
wherein the reference voltage generating circuit is configured to adjust the reference voltage,
wherein the regulator circuit is configured to change the output ratio of the power supply voltage to the reference voltage, and
wherein the semiconductor device further includes a voltage control circuit configured to output a voltage control signal to the regulator circuit to change the output ratio.

2. The semiconductor device according to claim 1, further comprising:
a non-volatile memory circuit configured to store a trimming code used to adjust the reference voltage, and
a trimming code supply circuit configured to supply the trimming code read from the non-volatile memory circuit to the reference voltage generating circuit.

3. The semiconductor device according to claim 1,
wherein the voltage control circuit, when the power supply voltage exceeds a first threshold, changes the output ratio from a first output ratio to a second output ratio smaller than the first output ratio.

4. The semiconductor device according to claim 2,
wherein the memory circuit is further configured to notify the timing information of supply the voltage control signal to the voltage control circuit.

5. The semiconductor device according to claim 1, further comprises:
an oscillator configured to generate a clock signal; and
a counter configured to count the number of pulses of the clock signal,
wherein the counter is further configured to notify the timing information of supply the voltage control signal to the voltage control circuit based on the number of pulses.

6. The semiconductor device according to claim 3, further comprises a voltage detection circuit configure to detect that the power supply voltage exceeds the first threshold voltage.

7. The semiconductor device according to claim 6,
wherein the reference voltage generation circuit comprises:
a bandgap reference circuit that generates a bandgap reference voltage;
an operational amplifier;
a ladder resistor connected between an output terminal of the operational amplifier and a ground terminal; and
a selector circuit configured to select one node from a plurality of nodes on the ladder resistor and output the voltage of the one node to an input terminal of the operational amplifier,
wherein the bandgap voltage is outputted to the operational amplifier, and
wherein the reference voltage is adjusted by the selector circuit.

8. The semiconductor device according to claim 7,
wherein the first threshold is the voltage of a certain node of the plurality of the nodes, and
wherein the voltage of the certain node is supplied to the voltage detection circuit.

9. The semiconductor device according to claim 6,
wherein the voltage detection circuit outputs a voltage guarantee signal when the power supply voltage exceeds a first threshold, and
wherein the voltage detection circuit stops outputting the voltage guarantee signal when the power supply voltage falls less than a second threshold signal smaller than the first threshold voltage.

10. The semiconductor device according to claim 2, wherein the power supply voltage is supplied to the non-volatile memory circuit.
